(19) United States
(12) Patent Application Publication
(10) Pub. No.: US 2001/0015467 A1
(43) Pub. Date: Aug. 23, 2001

(54) Transistor for a semiconductor device and method for fabricating same

(76) Inventors: Tae Hyoung Huh, Kyoungki-do (KR); Joong Shik Shin, Seoul (KR)

Correspondence Address: Pillsbury Winthrop LLP, Intellectual Property Group, Ninth Floor, East Tower, 1100 New York Avenue, NW., Washington, DC, 20005-3918, US

(21) Appl. No.: 09/751,846

(22) Filed: Jan. 2, 2001

(30) Foreign Application Priority Data
Dec. 31, 1999 (KR) 1999-67974

(51) Int. Cl. H01L 21/332; H01L 29/76; H01L 31/062; H01L 29/94; H01L 31/113; H01L 31/119

(52) U.S. Cl. 257/409; 438/140

(57) ABSTRACT

The present invention discloses a method for fabricating a transistor for a semiconductor device. The transistor requires and controls a high voltage, when using an anti-fuse circuit capable of carrying out a repair operation after packaging, thereby improving the operation property and yield of the device.

### BACKGROUND OF THE INVENTION

1. Field of the Invention

The present invention relates to a transistor for a semiconductor device and a method for fabricating thereof and, in particular, to a high-voltage transistor which is essential for forming an electric fuse circuit and a method for fabricating such transistors.

2. Description of the Background Art

In general, when any of the memory cells has a defect, a semiconductor memory device such as a DRAM and an SRAM cannot operate properly and must be discarded.

This is true even when defects occur in only a few cells, the whole chip is considered to be inoperable. It is thus inefficient to disuse the semiconductor memory device due to the cell defect. Accordingly, a redundancy method has been suggested for improving a yield by replacing a defective cell with a good spare cell provided on the semiconductor memory device, such as the DRAM and SRAM.

The conventional semiconductor memory device utilizing the redundancy method is typically then packaged according to the normal production process to form a molded package. When a defect is detected after the molded package has been formed, whether a chip has been replaced with a spare cell must be investigated as a step in analyzing the factors leading to the defect. In addition, in order to increase the reliability of the chip defective cells that were replaced with the spare cells must also be checked.

In order to investigate the chip using an optical method, the body of the molded package must be taken apart. However, the chip properties may be changed or the chip damaged during the package removal, rendering the chip unsuitable for failure analysis.

Therefore, in order to avoid these problems a test method for confirming whether the chip includes one or more spare cells without opening the molded package has been provided. In this test method, a fuse and a diode are connected in series between a special pin and a power pin, and a current flowing therebetween is varied depending on the state of the chip. Accordingly, whether the chip has been replaced with the spare cell can be confirmed without opening the package.

A fuse may be employed to replace the defective cell of the memory device with a replacement row and column, to perform an option treatment of a semiconductor integrated circuit, or to make minute adjustments to a unit device in the integrated circuit.

Various fusing methods have been used including forming a metal fuse and cutting the fuse by flowing a large current, a metal or polysilicon fuse and cutting the fuse by using a laser, and forming an insulated floating gate that can be charged with tunneling electrons.

These fusing methods have disadvantages in that the device repair expenses are high and the back end yield is low because a repair operation cannot be performed after packaging.

In order to overcome the aforementioned disadvantages, an anti-fuse is employed to carry out the repair operation after the packaging.

A conventional transistor has a junction breakdown voltage of about 3 to 8V, and thus is suitable for use in a semiconductor memory device. However, when the anti-fuse technique is applied to the circuit, a high voltage of 7 to 8V is used. This high voltage, when applied to a transistor drain region, results in a breakdown of the drain region junction.

### SUMMARY OF THE INVENTION

Accordingly, it is an object of the present invention to provide a transistor for a semiconductor device and a method for fabricating such transistors, that can increase the breakdown voltage of a drain region by surrounding a high voltage applied to the n+ diffusion layer with a lightly-doped n-well, and thereby prevent Miller breakdown voltage from being applied between the well and gate by positioning an insulating film between the well and the gate electrode.

In order to achieve the object of the present invention, a transistor for a semiconductor device consists of:

An insulating film for defining an active region on a p-type semiconductor substrate;

A p-well formed at one side of the p-type semiconductor substrate;

A n-well formed at the other side of the p-type semiconductor substrate, adjacent to the p-well;

A stacked structure of a gate insulating film pattern and a gate electrode which has a connection portion with the n-well and p-well being exposed by the insulating film, being formed at the connection with the n-wells and p-wells and at the insulating film; and

n+ diffusion layers formed at the p-wells and n-wells.

In order to achieve the above-described object of the present invention, there is provided a method for fabricating a transistor for a semiconductor device including the steps of: forming a device isolating insulating film for defining an active region on a p-type semiconductor substrate; forming a p-well at one side of the p-type semiconductor substrate and an n-well at the other side thereof, a connection portion of the p-well and the n-well being exposed to the device isolating insulating film; forming a stacked structure of a gate insulating film pattern and a gate electrode at the connection portion with the n-well and p-well and at the upper portion of the device isolating insulating film;

and increasing a breakdown voltage of the n-well which becomes a drain region by forming n+ diffusion layers at the n-well and the p-well exposed by the gate electrode and the device insulating film, and preventing a Miller break down voltage from being applied between the n-well and the gate electrode.

### BRIEF DESCRIPTION OF THE DRAWINGS

The present invention will become better understood with reference to the accompanying figures. These figures are provided only by way of illustration and thus are not intended to limit of the present invention unnecessarily.

FIG. 1A to FIG. 1C are cross-sectional views respectively illustrating sequential steps of a method for fabricating a transistor for a semiconductor device in accordance with a first embodiment of the present invention; and

FIG. 1D is a cross-sectional view illustrating a transistor for a semiconductor device in accordance with a second embodiment of the present invention.

### DETAILED DESCRIPTION OF THE PREFERRED EMBODIMENTS

A transistor for a semiconductor device and a method for fabricating thereof in accordance with the present invention will now be described in detail with reference to the accompanying figures.

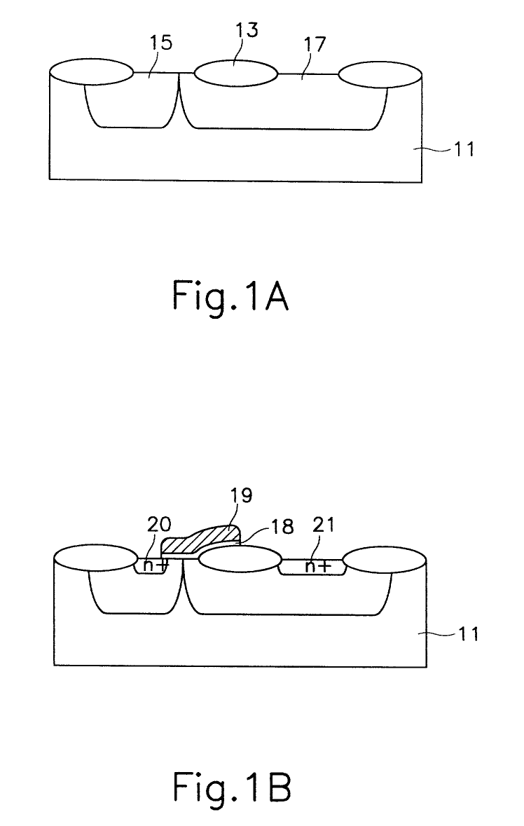

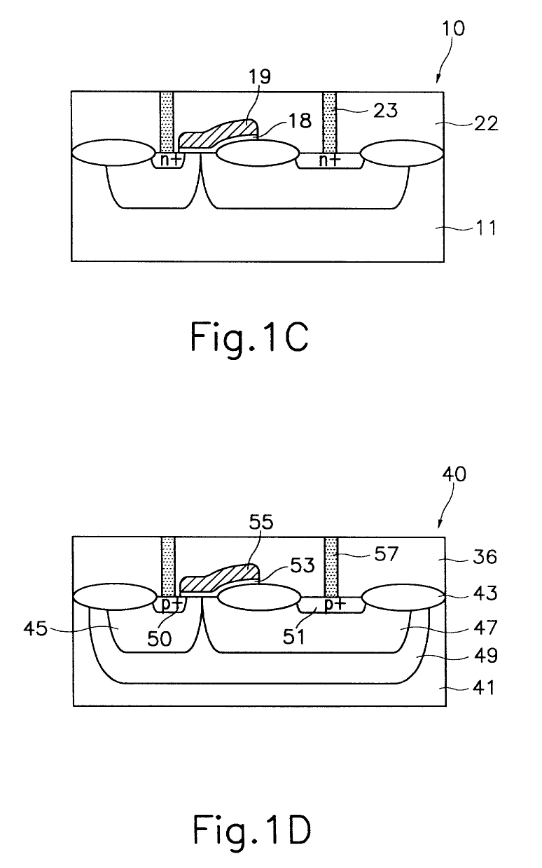

As shown in FIG. 1A device isolating film 13 is formed on predetermined device isolating regions of a p-type semiconductor substrate 11, thereby defining an active region for forming a transistor.

A p-well 15 is formed at one side of the p-type semiconductor substrate 11 and an n-well 17 is formed at the other side thereof Here, the p-well 15 and the n-well 17 are formed adjacent to each other.

As shown in FIG. 1B, a gate insulating film 18 and a gate electrode 19 are formed over both sides of the p-well 15 and the n-well 17. One side of the gate electrode 19 is formed over the device isolating film 13 positioned in the n-well 17.

Next, an n+ impurity is implanted into the portions of the p-well 15 and the n-well 17 that are exposed by the gate electrode 19 and the device isolating film 13, thereby forming n+ diffusion layers 20, 21.

As shown in FIG. 1C, an interlayer insulating film is formed over the whole surface and a contact hole is formed to expose the intended contact portions of the n+ diffusion layers 20, 21. A contact 23 connected to the n+ diffusion layers 20, 21 through the contact hole is formed, thereby forming an n-type transistor 10.

As shown in FIG. 1C, the transistor of the present invention for an anti-fuse circuit forms the gate electrode over the both sides of the adjacent p-well 15 and n-well 17, forming the gate electrode 19 over the device isolating film 13 in the n-well 17.

When a high voltage is applied to the n+ diffusion layer 21 in the transistor 10, the voltage is applied to the n-well 17, and thus the n-well 17 serves as a drain. Since the n-well 17 is lightly doped, a breakdown voltage is increased. In addition, the gate insulating film pattern 18 is formed between the n-well 17 and the gate electrode 19, thereby overcoming Miller breakdown voltage applied from the n well 17 to the gate electrode 19.

FIG. 1D is a cross-sectional view illustrating a transistor for a semiconductor device in accordance with a second embodiment of the present invention, in a state where a triple well is used.

A device isolating film 43 is formed on a p-type semiconductor substrate 41, thereby defining an active region for a transistor.

An n-well 49 is formed at a lower portion of the active region in the p-type semiconductor substrate 41.

A p-well 47 is formed at one side of the n-well 49, and an n-well 45 is formed at the other side thereof.

A gate insulating film 53 and a gate electrode 55 are formed over both sides of the p-well 47 and the n-well 45.

One side of the gate electrode 55 is formed over the device isolating insulating film 43 positioned in the p-well 47.

A p+ impurity is implanted into the portions of the p-well 47 and the n-well 45 that are exposed by the gate electrode 55 and the device isolating insulating film 43, thereby forming p+ diffusion layers 50, 51.

An interlayer insulating film 36 is formed over the whole surface, and a contact hole is formed to expose the intended contact portions of the p+ diffusion layers 50, 51. A contact 57 connected to the p+ diffusion layers 50, 51 through the contact hole is formed, thereby forming a p-type transistor.

The operation principle of the p-type transistor is identical to the n-type transistor. However, in this case, the n-well 45 and the p-well 47 are surrounded by the n-well 49, and thus the high voltage applied to the p+ diffusion layer 51 is not discharged to the p-type semiconductor substrate 41 through the p-well 47.

As discussed earlier, the method for fabricating the transistor for the semiconductor device in accordance with the present invention forms the transistor for controlling a high voltage, when using the anti-fuse circuit capable of performing a repair operation after completion of the packaging process, thereby improving the operational properties and yield of the semiconductor memory device.

As the present invention may be embodied in several forms without departing from the spirit or essential characteristics thereof, it should also be understood that the above-described embodiments are not limited by any of the particular details of the foregoing description, unless otherwise specified, but rather should be construed broadly within its spirit and scope as defined in the appended claims, and therefore all changes and modifications that fall within the meets and bounds of the claims, or equivalences of such meets and bounds are therefore intended to be embraced by the appended claims.

What is claimed is:

1. A transistor for a semiconductor device, comprising:
an insulating film for defining an active region on a p-type semiconductor substrate;
a p-well formed in the p-type semiconductor substrate, the p-well being located in a first portion of the active region;
a n-well formed in the p-type semiconductor substrate, the n-well being located in a second portion of the active region and adjacent the p-well;
a stacked structure of a gate insulating film pattern and a gate electrode, the stacked structure being positioned over the adjacent n-well and p-well in the active region; and
heavily doped diffusion regions formed in the p-well and the n-well.

2. The transistor of claim 1 wherein the heavily doped diffusion regions are n+ diffusion regions.

3. The transistor as claimed in claim 1, wherein the p-well and the n-well are formed in a deep n-well at the lower portion of the p-type semiconductor,
and wherein the heavily doped regions are p+ diffusion regions.

4. A method for fabricating a transistor for a semiconductor device, comprising the steps of:
forming a device isolating film for defining an active region on a p-type semiconductor substrate;
forming a p-well at one side of the p-type semiconductor substrate and an n-well at the other side thereof, a connection portion of the p-well and the n-well being exposed by the device isolating film;
forming a stacked structure of a gate insulating film pattern and a gate electrode positioned over the connection portion of the n-well and p-well, the stacked structure extending over a portion of the device isolating film; and
increasing a breakdown voltage of the n-well which acts as a drain region, by forming a heavily doped region in a portion of the n-well exposed by the stacked structure and a portion of the p-well exposed by the stacked structure, thereby preventing Miller breakdown voltage from being applied between the n-well and the gate electrode.

5. The method for fabricating a transistor as claimed in claim 4, further including step of:
forming heavily doped regions comprising n+ diffusion regions in the n-well an p-well.

6. The method for fabricating a transistor as claimed in claim 4, further including steps of:
forming a deep n-well at the lower portion of the p-type semiconductor substrate;
forming the n-well and the p-well in the deep n-well; and
forming heavily doped regions comprising p+ diffusion regions in the n-well an p-well.
